(19) United States
(12) Patent Application Publication
(10) Pub. No.: US 2026/0276691 A1
(43) Pub. Date: Sep. 17, 2026

(54) METHOD FOR DETECTING PRESENCE OF AN ELECTRIC ARC AND ASSOCIATED DEVICE

(71) Applicants: SAFRAN, PARIS (FR); CENTRE NATIONAL DE LA RECHERCHE SCIENTIFIQUE, PARIS (FR); ECOLE SUPERIEURE DE PHYSIQUE ET DE CHIMIE INDUSTRIELLE DE LA VILLE DE PARIS, PARIS (FR); SORBONNE UNIVERSITE, PARIS (FR)

(72) Inventors: Raul CARREIRA RUFATO, MOISSY CRAMAYEL (FR); Emmanuel BUSSY, MOISSY CRAMAYEL (FR); Thierry Michel André LEBEY, MOISSY CRAMAYEL (FR); Yacine OUSSAR, PARIS (FR); Thierry DITCHI, LEUVILLE-SUR-ORGE (FR)

(21) Appl. No.: 19/166,767

(22) PCT Filed: Mar. 20, 2024
(86) PCT No.: PCT/FR2024/050334

§ 371 Date: Sep. 18, 2025

(30) Foreign Application Priority Data
Mar. 20, 2023 (FR) FR2302544
Mar. 20, 2023 (FR) FR2302545

(51) Int. Cl. G01R 31/12; H02H 1/00

(52) U.S. Cl. CPC G01R 31/1272; H02H 1/0015; H02H 1/0092

(57) ABSTRACT

A computer-implemented method for detecting the presence of an electric arc on a power line using a machine learning algorithm, carried out using a time-correlated measurement of the arc voltage V_{arc}, of the current I and of the source voltage V_{source} and also a knowledge model for linking the arc voltage V_{arc} and the current I to constants depending on the knowledge model, implemented after a learning phase that involves adjusting a learning model that takes the current I and the source voltage V_{source} at input and provides the voltage V_{arc} and the constants of the knowledge model at output; the method including continuously detecting the presence of an arc using a decision function depending on a cost function used in the learning phase.

### TECHNICAL FIELD OF THE INVENTION

The technical field of the invention is that of detecting presence of an electric arc using a machine learning method.

The present invention relates to a process and device for detecting presence of an electric arc using a learning method, and in particular a method in which a learning model and a knowledge model are used in conjunction.

### TECHNOLOGICAL BACKGROUND OF THE INVENTION

Civil aviation has been mobilising for several years now to contribute to the fight against climate change.

Technological research effort has already led to very significant improvements in the environmental performance of aeroplanes. This application is the result of taking account of factors that have an impact on all phases of design and development in order to obtain aeronautical components and products that are less energy-intensive, more environmentally friendly and whose integration and use in civil aviation have a moderate environmental impact, with the aim of improving energy efficiency of aeroplanes.

In other words, the present invention is the result of ongoing work to reduce the climate impact of civil aviation through the use of methods and the exploitation of virtuous development and manufacturing processes that minimise greenhouse gas emissions as much as possible in order to reduce the environmental footprint of its activity. As shown in the present invention, this ongoing research and development work especially focuses on the development of employing electrical technologies for propulsion. Within the scope of this context, it is particularly important to be able to detect formation of electric arcs.

For the record, an electric arc is a self-sustaining high-current discharge. There are two main types of electric arcs that occur in an aeronautical environment: cut-off arcs, which occur in contactors when a circuit is opened or closed, and fault arcs, which can occur unexpectedly on all the components in the electrical system. The same can cause severe damage to equipment, systems and even of the aircraft structure. It is therefore a particular point of vigilance.

There are two types of fault arcs, as a function of their position on the electrical circuit: parallel arcs and series arcs. Series arcs generally occur at the terminals of an intermediate interface (connecting terminal block, connector) following a connection problem during maintenance/installation, or when the interface exhibits signs of degradation due to natural ageing or premature ageing caused by chemical, electrical or mechanical interactions.

On an electrical distribution network, series arcs are always more difficult to detect compared to parallel arcs. Indeed, from an electrical signature point of view, parallel arcs generate a high current demand, which allows real-time diagnostic systems to identify them quickly and effectively in order to give a command to the cut-off system to protect the line. In contrast, in the case of a series arc, the current is only slightly impacted. This is because an electric arc is a low-impedance fault. As a result, when an arc is present in series on the electrical system, the current will only suffer a slight fluctuation, more precisely a reduction of a small percentage of its nominal value. This is the main reason why series arcs are more difficult to detect using standard control means compared to parallel arcs. In addition, the waveform of the electrical signal from the network is also a factor that can complicate detection. Relating to alternating current networks, during the half-period, passing through a voltage of 0 V is the moment when the electric arc can no longer continue. When a series arc occurs on this type of network, this moment can result in a brief open circuit, leaving the line current at 0 A for a short time (this phenomenon places current shoulders), which can be used to diagnose a series arc fault. On the contrary, when the waveform is direct (DC network), this phenomenon no longer exists and the arc persists without an open circuit, thus eliminating one of the possibilities for diagnosing the fault.

On current networks, due to the relatively moderate power distributed, the occurrence of electric arcs is mitigated because the voltage levels distributed in aeronautics are maximum at 230/400V. Further, distribution is in the form of alternating (AC) waveform for these voltage levels (230/400V maximum), which promotes self-extinguishing of the arc at each half-period when the voltage passes through 0V. Furthermore, the distribution of direct current (DC) is predominantly limited to 28V. The impact of electric arcs is also limited by the use of passive protection (choosing “arc-resistant”materials, defining segregation distances) in order to limit consequences of fault arcs on the environment, as well as by the use of active protection (detection and line opening) in the event of an overcurrent fault observed by current sensors. This has the advantage of providing detection for most parallel arcs, but not series arcs, for which no active protection has been deployed to date.

Current work on the electrification/hybridisation of aircraft contemplates the distribution of direct current (DC) waveforms at voltage levels of up to one kilovolt. This paradigm calls into question the arc fault passivation strategy that has just been discussed. Series electric arc must therefore be taken into account in the same way as parallel arc, as the damage associated with the generation of higher-power faults subjected to DC voltage may damage the aircraft and compromise the safety of passengers and crew.

One means to mitigate series arc faults is to identify (detect) them in order to isolate the faulty line, if necessary.

The major problem raised by the detection of electric arcs in aeronautics is based on high performance expectations. More particularly, the first requirement is reliability, i.e. the ability of a system to systematically detect dangerous electrical phenomena in all circumstances. This refers to its ability to achieve a true positive rate as close to 100% as possible. The second requirement is robustness, i.e. the ability of a system to be immune to any event other than the one for which it has been programmed. In other words, it is its ability to achieve a false positive rate as close to 0% as possible. The system must therefore be robust in the face of different aeroplane load signatures (with behaviours similar to arc signatures) as well as all the environmental parameters associated with aircraft flight and life cycles.

Until now, existing solutions for arc detection have consistently shown weaknesses, either in terms of reliability or robustness. There are multiple reasons for this, but it is worth mentioning the inaccuracy of the fault arc models used to calibrate the systems, the lack of knowledge (or simplification) of the targeted electrical architecture, or even the environmental constraints encountered, all of which reduce the performance of the technologies provided.

In order to meet these high requirements, new methods are being sought. Among them, machine learning methods are beginning to be increasingly used. They offer new alternative solutions. These methods are divided, especially, into unsupervised learning, semi-supervised learning, supervised learning or even reinforcement learning.

The branch most commonly applied to the detection of electrical faults in the state of the art is supervised learning. This type of learning is a group of methods aimed at generating a function capable of relating the set of inputs to an output using a base of examples and sophisticated mathematical methods. The model deduces this function from labelled data consisting of a set of learning examples. Detection methods using a model obtained through supervised learning are divided into regression and classification methods.

The objective of classification is to predict a discrete value that allows any piece of data to be assigned to a category referred to as a class. The decision function obtained by a classification method therefore separates existing classes. The objective of regression is to predict a continuous amount. The decision function obtained by regression will therefore be able to represent the behaviour of the system studied by continuously representing the quantity of interest (rather than discretely, as classification does).

In the state of the art, electric arc detection (including in aeronautical environments) is generally performed on the basis of electrical measurements using supervised machine learning, but in the state of the art, the labelling method used is not specified, or the labelling method is specified but does not correctly identify all phenomena. For example, in the state of the art, an arc voltage measurement can be used to complete the labelling. Document entitled “AC Series Arc-Fault Detection With A Transformer Neural Network, A Chabert et al., June 2022” provides AC series arc detection using a supervised learning method. A fully automatic labelling algorithm is provided using arc voltage.

However, known solutions using machine learning tools designed for arc detection, such as fault arcs, sometimes lack representativeness. Generally, their labelling methods (essential for this approach) are not described and/or are not precise enough with regard to the erratic nature of electric arcs. However, if the labelling step is not carried out correctly, by including all the phenomena contemplated for the detection step, the learning step will be biased and will produce a detection tool with poor performance in a real environment.

In order to detect fault arc formation, document EP3695476 A1 provides detection by machine learning using a recurrent neural network. This is a detection method that uses only the mathematical information provided by machine learning tools. In particular, in the method provided, the learning phase does not use physical arc equations. Document “Physics-Informed Learning for High Impedance Faults Detection, Wenting Li, Deepjyoti Deka, 2021 IEEE Madrid PowerTech” provides a so-called physics-informed detection method for high impedance faults in microgrids (this is therefore not the same type of discharge as that produced by an electric arc). More particularly, detection is based on a method derived from machine learning as well as knowledge of the physics of the phenomenon to be detected. However, in this document, the physical information does not come from a complete model of knowledge of the discharge behaviour. The physical information relating to the discharge is indeed derived from a measurement of the difference between a voltage-current phase diagram in a network without faults and one with faults.

Thus, state-of-the-art methods do not generally provide the reliability and robustness required for use in aeronautics. There is therefore a need for a method for detecting electric arcs that can significantly improve detection capability of existing methods, especially for series arcs.

### SUMMARY OF THE INVENTION

The invention offers a solution to the problems previously discussed by providing a detection method based on an approach that uses both experimental data and physical knowledge to design a semi-physical arc detection model through learning.

For this, a first aspect of the invention relates to a computer-implemented process for detecting presence of an electric arc on an electric line using a machine learning method, the learning being performed using:
a plurality of measurements relating to the formation of an electric arc, each measurement of the plurality of measurements comprising a time-correlated measurement of the arc voltage V_{arc}, the current I and the source voltage V_{source};
a knowledge model relating the arc voltage V_{arc} and the current I to constants depending on the knowledge model.

The process according to one aspect of the invention is implemented using a learning model derived from a learning phase during which, using the plurality of measurements and the knowledge model, a learning model adjustment step is implemented, the learning model taking as inputs the current I and the source voltage V_{source} and providing as outputs the arc voltage V_{arc} and the constants of the knowledge model, the learning being performed using a cost function L given by the following relationship L=L₁+L₂ where L₁ is a first cost sub-function measuring a first difference between the arc voltage

$${V}_{arc}^{predit}$$

predicted by the learning model and the arc voltage measured V_{arc}:

$${L}_{1} = ‖ {V}_{arc}^{predit} - {V}_{arc} ‖$$

and where L₂ is a second cost sub-function measuring a second difference between the prediction of the knowledge model and the measurement values.

The method according to one aspect of the invention comprises a detection phase including:
A step of continuously measuring the current I and the source voltage V_{source} on the electric line, so as to acquire input data relating to the current I and the source voltage V_{source} over a measurement window

$${\{ I ( {t}_{m} ) , {V}_{source} ( {t}_{m} ) \}}_{m = 1}^{M}$$

where M is the number of measurement points in the measurement window, I(tₘ) is the current at time tₘ and V_{source}(tₘ) is the source voltage at time tₘ;
A step of continuously determining the presence of an arc, using a decision function for detecting, as a function of the M last input data relating to the current I and the source voltage V_{source} measured on the electric line during the measurement step, presence of an arc, the decision function being a function of the second cost sub-function.

By virtue of the invention, it is possible to use arc physics (based on electric arc knowledge models) to predict part of the behaviour of a fault arc and thus contribute to model learning. This makes it possible to make a more effective decision than solutions provided by the state of the art, and to reduce the amount of raw data required for learning (for example, by limiting the amount of load signals derived from the aeroplane architecture), compared to a learning model according to the state of the art. This result is obtained especially by combining experimental information with a physical law. Furthermore, the variation in arc length does not need to be known a priori, as it appears implicitly in the variables of the knowledge model.

Further to the characteristics just discussed in the preceding paragraph, the process according to a first aspect of the invention may have one or more of the following additional characteristics, considered individually or according to all technically possible combinations.

In one embodiment, the decision function is defined by the following expression:

$$f ( X ) = \{ \begin{matrix}Arc & if {\sum }_{m = 1}^{M} {L}_{2} ( {X}_{m} ) \leq ε \\ Else & if {\sum }_{m = 1}^{M} {L}_{2} ( {X}_{m} ) > ε\end{matrix}$$

Where Xₘ={I(tₘ),V_{source}(tₘ)}, ε is a detection threshold value, and L₂(Xₘ) is the value of the second cost sub-function L₂ determined using the learning model and calculated at point Xₘ.

In one embodiment, the knowledge model is the Mayr model and the second cost sub-function L₂ takes the following form:

$${L}_{2} = \frac{1}{I} \frac{dI}{dt} - \frac{1}{{V}_{arc}} \frac{{dV}_{arc}}{dt} - \frac{1}{τ} ( \frac{{V}_{arc} I}{{P}_{0}} - 1 )$$

where τ is the arc constant and P₀ is the cooling power.

In one embodiment, the knowledge model is the Cassie model and the second cost sub-function L₂ takes the following form:

$${L}_{2} = \frac{1}{I} \frac{dI}{d t} - \frac{1}{{V}_{a r c}} \frac{d {V}_{a r c}}{d t} - \frac{1}{τ} ( \frac{{V}_{arc}^{2}}{{V}_{0}^{2}} - 1 )$$

where τ is the arc constant and V₀ is a constant corresponding to a minimum arc voltage (i.e., a minimum voltage value on the electric line where the arc occurs).

In one embodiment, the knowledge model is the Shavemaker model and the second cost sub-function L₂ takes the following form:

$${L}_{2} = \frac{1}{I} \frac{dI}{d t} - \frac{1}{{V}_{a r c}} \frac{d {V}_{a r c}}{d t} - \frac{1}{τ} ( \frac{{V}_{a r c} I}{{P}_{0} + {V}_{0} \vert I \vert} - 1 )$$

where τ is the arc constant, P₀ is the cooling power, and V₀ is a constant corresponding to a minimum arc voltage (i.e., a minimum voltage value on the electric line where the arc appears).

In one embodiment, the electric line is equipped with a cut-off device for cutting off the current in said line, the method comprising, when an electric arc is detected during the detection step, a step of sending an instruction to the cut-off device to cut off current on the line considered.

In one embodiment, the learning model is made using a formal neural network.

In one embodiment, the learning model is made using a support vector machine.

There is therefore a need for a data labelling method that makes it possible to obtain data representative of the phenomenon of fault arc formation, especially data representative of a series arc of the DC voltage type. There is also a need for a detection method making use of data labelled with the method in question during the learning phase.

In one embodiment, the method can offer a solution to the problems discussed previously by ensuring that data from electrical measurements of fault arcs are correctly labelled and by allowing:
This binary labelling (arc or non-arc) to be associated with a supervised machine learning classification method;
Ensuring that an arc is detected in a robust and reliable manner;
Automated arc detection.

Another purpose of the method may be to optimise the time spent labelling data during the model training phase for the detection of electric arcs and to reduce resources required for labelling.

For this, in one embodiment, the method comprises:
a design phase involving machine learning of a decision function using the plurality of measurements, the design phase comprising:
   For each measurement of the plurality of measurements, a step of labelling the arc current measurement using the arc voltage measurement associated therewith;
   a step of extracting descriptors from the measurements labelled;
   a learning step for determining the decision function from at least one part of the descriptors extracted in the extraction step;
the detection phase comprising:
   A step of measuring the current flowing on the line;
   A step of extracting descriptors from the current measurement obtained during the preceding current measurement step;
   From the descriptors extracted from the current measurement and using the decision function determined during the design phase, a step for detecting presence of arcs.

Furthermore, in the process according to this embodiment, the labelling step comprises, for each of the plurality of measurements and for each time interval t of the measurement considered:
When the arc voltage U_{arc} measured exceeds a predetermined threshold value Uₛ for the first time, a step of recording the interval considered to be the starting point t_{d} of the electric arc;
When the arc voltage U_{arc} measured falls back below the predetermined threshold value Uₛ for the first time, a step of recording the interval preceding the interval considered to be the end point tₑ of the electric arc.

By virtue of the process, the labelling logic combines arc physics, an automated procedure and, in some cases, human expertise. Thus, it becomes possible to correctly label the vast majority, if not all, arc or nominal signals, to perform this labelling efficiently by virtue of the automated procedure, to correct algorithmic inaccuracies caused by the variability in arc signatures (when human expertise is requested), label windows as precisely as possible (to within one sample), and create a database that is labelled and adapted to the design of a machine learning classifier for the detection of electric arcs.

This embodiment of the process may form a detection process in its own right, the process being computer implemented and using a machine learning method, the learning being performed using a plurality of measurements relating to the formation of electric arcs, each measurement of the plurality of measurements comprising a time-correlated measurement of the arc voltage and the arc current, the method comprising the steps of this embodiment as described previously.

In one embodiment, for each measurement, the labelling is associated with a measurement window on which learning is performed, said window being given by the interval P_{g}×min((tₑ−t_{d}),Tₘₐₓ); P_{d}×min((tₑ−t_{d}),Tₘₐₓ) where Tₘₐₓ is a predefined maximum window duration, P_{g} is a left pitch of point t_{d} having a normalised value for the duration of the window under study, and P_{d} is a right pitch of point ta having a normalised value for the duration of the study window given by the relationship P_{d}=1−P_{g}.

In one embodiment, the method comprises, prior to the learning phase, a step of acquiring signals necessary for learning so as to obtain a plurality of measurements, each measurement comprising a time-correlated measurement of the arc voltage and the arc current.

In one embodiment, the design phase comprises, prior to the labelling step, a step of manually pre-identifying, by expertise, in each of the plurality of measurements, all electric arcs satisfying predetermined criteria so as to define a position of each arc within each of the plurality of measurements.

In one embodiment, the design phase includes, after the labelling step, a step of manually verifying outputs of the labelling step by expertise so as to verify that the measurements labelled include all the regions contemplated for learning.

In one embodiment, the descriptors used during the decision function determination step include spectral entropy and/or autocorrelation of the arc current.

In one embodiment, the design phase includes, between the descriptor extraction step from the measurements labelled and the decision function determination step, a descriptor classification and selection step so as to retain the most relevant subset of descriptors. For example, the classification may be performed using a Gram-Schmidt method and the selection may be performed using an incremental method. Of course, other methods may be used for classification or selection.

In one embodiment, the decision function determination step comprises a plurality of iterations of the following two sub-steps:
a sub-step of designing a classifier through learning; and
a sub-step of validating the classifier based on the data labelled;
   These sub-steps being repeated until an optimal classifier is obtained, the decision function being determined from this optimal classifier.

A second aspect of the invention relates to a device for detecting presence of an arc in an electric line comprising a measurement means configured to measure the current flowing in the electric line and means configured to implement the method according to the first aspect of the invention.

A third aspect of the invention relates to a computer program comprising instructions which, when executed by a computer, cause the device according to the second aspect of the invention to execute the method according to the first aspect of the invention.

A fourth aspect of the invention relates to a computer-readable medium having the computer program according to the third aspect of the invention recorded thereon.

A fifth aspect of the invention relates to an aircraft comprising the arc detection device as defined hereinbefore.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 shows a first flowchart of the process according to one exemplary embodiment of the invention.

FIG. 2 shows a second flowchart of a process according to an example of the invention.

FIG. 3 shows a schematic representation of an arc voltage measurement and an arc current measurement correlated in time.

FIG. 4 shows a schematical representation of arc voltage measurement and an arc current measurement correlated in time after pre-identification.

FIG. 5 shows a flowchart of a labelling step according to one example of the invention.

FIG. 6 shows a schematic representation of the labelling principle according to the invention based on a arc voltage measurement and an arc current measurement correlated in time.

FIG. 7 shows a schematical representation of arc voltage as a function of the arc length.

FIG. 8 shows a schematic representation of a device according to one exemplary embodiment of the invention.

### DETAILED DESCRIPTION

The figures are set forth by way of indicating and in no way limiting purposes of the invention.

### Process for Detecting Presence of an Electric Arc on an Electric Line

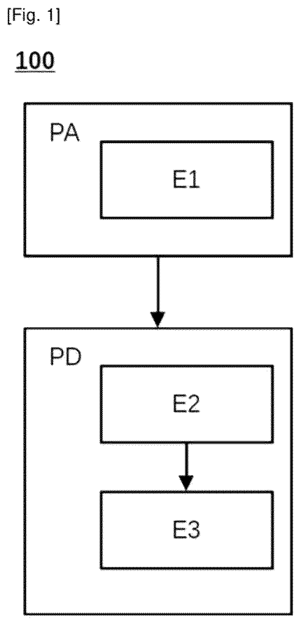

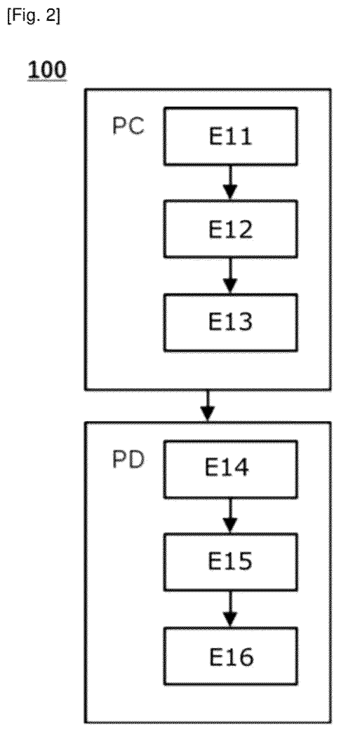

A first aspect of the invention illustrated in [FIG. 1] relates to a computer-implemented process 100 for detecting presence of an electric arc on an electric line using a machine learning method. More particularly, in the process according to the invention, learning is performed using a plurality of measurements relating to the formation of an electric arc, each measurement of the plurality of measurements comprising a time-correlated measurement of the arc voltage V_{arc}, the current I and the source voltage V_{source}.

The process according to the invention is especially original in that, in addition to a learning model, its design is also based on the use of a knowledge model for relating the arc voltage V_{arc} and the current I to constants that depend on the choice of knowledge model. More particularly, the principle of the present invention is based on the implementation of a learning phase PA that uses two techniques: machine learning modelling and knowledge modelling. This makes it possible to take advantage of the capacity of machine learning modelling and the expertise provided by the method derived from the physics of the fault arc mechanism.

For the record, learning modelling uses a mathematical regression tool derived from machine learning methods. For example, this tool can take the form of a formal neural network. However, this type of approach, sometimes referred to as “black box” modelling, where only measurements are used, has some limitations, especially because the database used during learning is not exhaustive and does not have all types of arcs to be detected.

Still for the record, knowledge modelling also makes it possible to describe, at least partially, the physical behaviour of the arc sought to be detected. However, this modelling also has some limitations. In particular, the generalisation of this method can be called into question: its domain of validity and its performance can, for example, be reduced by the high variability in the parameters of the arc and its environment.

The approach of the present invention provides a process 100 that corrects limitations of each of these methods by combining them. More particularly, in the process according to the invention, the knowledge model derived from the physics of the arc makes it possible to define a framework for the behaviour of the fault to be detected. Thus, in the case where data for adjusting the model by learning are rare, the knowledge model makes it possible to guide decision and not to deviate from the known operation of the mechanism under study, herein the fault arc.

On the other hand, any inaccuracy in the knowledge model can be adjusted by virtue of data that contains all the information on the variation in the quantities of interest. More precisely, learning the learning model is done by recognising arc signatures within the experimental data. Meantime, this learning phase has to be guided by expertise derived from one or more physical laws based on knowledge of arc physics.

In summary, in the present invention, arc detection is designed and adjusted by virtue of tools derived from machine learning and knowledge derived from the physics of the system.

### Learning Phase

The process according to the invention first comprises a learning phase. The purpose of this phase is to adjust the black box model using the knowledge model and thus obtain a decision function which, based on measurements taken on the electric line, gives a Boolean (or any other equivalent representation) representative of the presence or absence of a fault arc on the electric line.

In order to carry out this learning, it is necessary to have a plurality of measurements, each measurement of the plurality of measurements including a time-correlated measurement of the current I, the source voltage V_{source} and the arc voltage V_{arc}. By “time-correlated”, it is meant that a current measurement I, a source voltage measurement V_{source} and an arc voltage measurement V_{arc} with the same abscissa t have been measured at the same instant t.

If these measurements are not available, it may be necessary to collect the same, for example during laboratory measurements. For this, in one embodiment, the learning phase PA includes a step of acquiring a plurality of measurements, each measurement comprising a time-correlated measurement of the current I, the source voltage V_{source} and the arc voltage V_{arc}. As already mentioned, this step is generally implemented in a laboratory where tests are performed to generate a database comprising the plurality of raw measurements.

At the end of this step, a plurality of measurements is obtained, each measurement of this plurality of measurements being described using the following notation:

$${\{ I ( {t}_{m} ) , {V}_{a r c} ( {t}_{m} ) , {V}_{s o u r c e} ( {t}_{m} ) \}}_{m = 1}^{M}$$

where tₘ is the discretised time, I(tₘ) is the current as a function of tₘ V_{arc}(tₘ) is the arc voltage as a function of tₘ, V_{source} (tₘ) is the source voltage as a function of tₘ, and M is the total number of points available in the measurement considered.

The learning phase PA also comprises, using the plurality of measurements, a step E1 of adjusting a learning model that takes as input the current I and the source voltage V_{source} and providing as an output the arc voltage V_{arc} and constants associated with the selected knowledge model (example the arc constant τ and the cooling power P₀ when the knowledge model is the Mayr model). During this step E1, learning is performed using a cost function L to be minimised and given by the following relationship L=L₁+L₂. For the record, a cost function is a parameterisable function defining an error. The closer the result of the cost function is to 0, the smaller the error.

In the preceding relationship, the term L₁ is defined as the comparison of the output values calculated by the learning model with the values measured, this error being calculated only for the arc voltage V_{arc}. Accordingly, L₁ represents the difference between the arc voltage

$${V}_{a r c}^{p r e d i t}$$

predicted by the learning model and the arc voltage V_{arc} measured and given by the following equation:

$${L}_{1} = ‖ {V}_{a r c}^{p r e d i t} - {V}_{a r c} ‖$$

The term L₂ in turn represents the difference between the prediction of the knowledge model and the values measured. Its expression therefore depends on the knowledge model used. In any case, the knowledge model used must be able to provide the arc voltage V_{arc} as an output.

In one embodiment that will serve as an illustration in the rest of the description, the knowledge model used is the Mayr model. In this embodiment, the learning-adjusted model is made using a formal neural network.

In one alternative embodiment, the knowledge model is a Cassie model. In this embodiment, the learning-adjusted model can be made using a support vector machine.

In one alternative embodiment, the knowledge model is a Shavemaker model. In this embodiment, the learning-adjusted model can be made using a support vector machine.

In the following, and for illustrative purposes, the Mayr model will be used. For the record, the Mayr model is derived from the energy balance between the amount of energy lost due to cooling and that supplied by the circuit. In particular, the Mayr model provides the following dynamic equation:

$$\frac{d ln {G}_{a r c}}{d t} = \frac{1}{τ} ( \frac{{V}_{a r c}^{2} {G}_{a r c}}{{P}_{0}} - 1 )$$

where

$${G}_{a r c} = \frac{1}{{R}_{a r c}} = \frac{I}{{V}_{a r c}}$$

is the conductance of the arc column (neglecting the effect of the arc roots). This equation can be written as:

$$\frac{1}{I} \frac{dI}{d t} - \frac{1}{{V}_{a r c}} \frac{{dV}_{a r c}}{dt} = \frac{1}{τ} ( \frac{{V}_{a r c} I}{{P}_{0}} - 1 )$$

where τ is the arc time constant with τ=τ(T, P, l) and P₀ is the cooling power with P₀=P₀(T, P, l),T being the room temperature, P being the ambient pressure and l being the arc length.

The cost function L₂ can then be written as follows:

$${L}_{2} = \frac{1}{I} \frac{dI}{d t} - \frac{1}{{V}_{a r c}} \frac{d {V}_{a r c}}{d t} - \frac{1}{τ} ( \frac{{V}_{a r c} I}{{P}_{0}} - 1 )$$

The learning step therefore aims especially to adjust a mathematical model that will determine a function:

$$f : ( I ( {t}_{m} ) , {V}_{s o u r c e} ( {t}_{m} ) ) \to ( {V}_{a r c} ( {t}_{m} ) , τ , {P}_{0} )$$

More particularly, the learning algorithm uses the measurement values to determine the output variables (V_{arc}(tₘ), τ, P₀). However, only the arc voltage V_{arc}(tₘ) is available in the plurality of measurements. Therefore, the determination of the pair (τ, P₀) (in the case of the Mayr model), which must satisfy the equation, will be performed using the knowledge models that have been selected.

Thus, at the end of this step E1, the function ƒ previously introduced is determined (and no longer changes during the detection phase set forth hereinafter).

### Detection Phase PD

Once the learning phase is complete, the model obtained, which minimises L in the best way, is then able to correctly predict the outputs (V_{arc}(tₘ), τ, P₀) from the inputs (I(tₘ), V_{source}(tₘ)) coming from the arc signals.

During the detection phase PD, the model will thus receive an amount M of inputs

$${\{ I ( {t}_{m} ) , {V}_{s o u r c e} ( {t}_{m} ) \}}_{m = 1}^{M}$$

that represent a signal window acquired from sensors (typically the line current I and the source-side voltage V_{source}, but other quantities may be contemplated as a function of the knowledge model, such as temperature, pressure, etc.). Next, the learning model, through the function ƒ previously introduced, carries out prediction of M outputs

$${\{ {V}_{a r c} ( {t}_{m} ) , τ , {P}_{0} \}}_{m = 1}^{M} ,$$

which depend on the knowledge model selected. The outputs calculated by the model are used to evaluate the error function L₂ and thus determine whether the corresponding signal is an arc (if the prediction is correct, i.e. the value of the error function is low) or not (if the prediction is incorrect, i.e. the value of the error function is not low).

The principle stated in the preceding paragraph can be formulated simply using the error function L₂ previously introduced with the following expression:

$$Window = \{ \begin{matrix}Arc , if {\sum }_{m = 1}^{M} {L}_{2} \leq ε \\ Else , if {\sum }_{m = 1}^{M} {L}_{2} > ε\end{matrix}$$

The adjustment of the threshold value ε will depend on the availability of so-called nominal data. This threshold value may be more or less sensitive according to the field of application. It can be defined empirically (possibly by calibration), as a function of desired performance of the detection model. Performance measurements can, for example, be evaluated as the rate of false negatives and false positives.

Accordingly, the detection phase PD of the process according to the invention includes a step E2 of continuously measuring the current I and the source voltage V_{source} on the electric line. Based on these continuous measurements, it is then possible to create a window of M measurements, noted as

$${\{ I ( {t}_{m} ) , {V}_{s o u r c e} ( {t}_{m} ) \}}_{m = 1}^{M}$$

(previously introduced). Of course, this is a sliding window that changes with the course of measurements as they are acquired during measurement step E2.

It is from this sliding window that continuous detection of a fault arc is possible.

The detection phase PD also includes a step E3 of continuously determining the presence of an arc using a decision function for detecting, as a function of the M last input data relating to the current I and the source voltage V_{source} measured on the electric line during the measurement step, presence of an arc. The decision function is, according to one example, defined by the following expression:

$$f ( X ) = \{ \begin{matrix}Arc if {\sum }_{m = 1}^{M} {L}_{2} ( {X}_{m} ) \leq ε \\ Else if {\sum }_{m = 1}^{M} {L}_{2} ( {X}_{m} ) > ε\end{matrix}$$

$$Where {X}_{m} = \{ I ( {t}_{m} ) , {V}_{source} ( {t}_{m} ) \} .$$

In one embodiment, the electric line is equipped with a current cut-off device for cutting off current in the line on which the detection is performed, and the process 100 according to the invention comprises, when an electric arc is detected during step E3 of determining the presence of an arc, a step of sending an instruction to the cut-off device to cut off current on the line considered. This makes it possible to prevent or, at the very least, limit damage associated with the formation of an electric arc on the electric line considered.

### Design of a Learning Decision Function

In one embodiment, the process 100 according to the invention takes place in at least two phases, here called PC and PD:
a design phase PC for determining a decision function, i.e. a function that takes as an input a plurality of descriptors derived from a current measurement and gives as an output a Boolean (or any equivalent representation) representative of the presence or absence of an electric arc in the measurement considered;
a detection phase PD, during which the current on an electric line is measured so as to extract from this measurement descriptors identified during the design phase PC and detect the presence or absence of an electric arc using the decision function determined during the design phase PC.

Optionally, when the plurality of measurements required for the design phase is not available, the method may also include an acquisition phase aimed at obtaining said plurality of measurements.

### Acquisition of Measurements

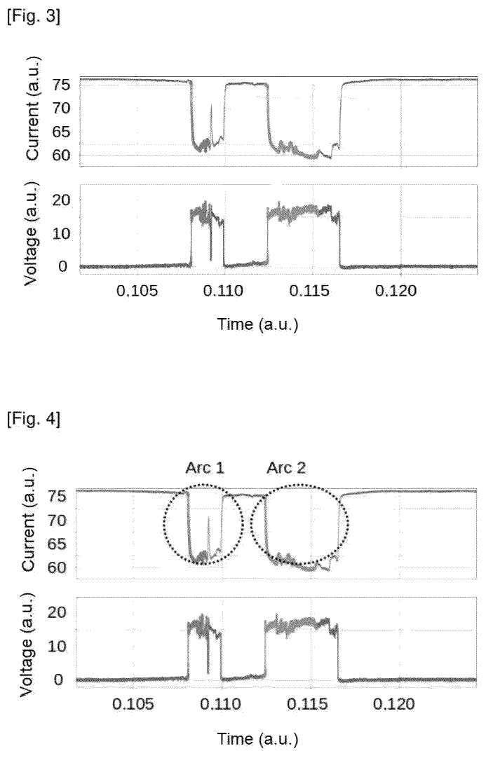

As already mentioned, it may be necessary to collect measurements if they are not available. For this, in one embodiment, the process 100 comprises, prior to the design phase PC, an acquisition phase comprising a step of acquiring a plurality of measurements, each measurement comprising a time-correlated measurement of the arc voltage and the arc current. Such a measurement is illustrated in [FIG. 3], setting forth the arc current measurement at the top and the corresponding arc voltage measurement at the bottom, with the two measurements being time-correlated (i.e., an arc current measurement and an arc voltage measurement having the same abscissa t have been measured at the same instant t). The electric line is, for example, an aircraft network electric line.

This phase is generally implemented in a laboratory where tests are performed in order to generate a database comprising the plurality of raw measurements. The raw measurements are also accompanied with information relating to the measurement, especially:
The sampling frequency during the measurement, for example 1 MHz;
The description of the signals measured, including:
   The arc current (or line current) measurement;
   The arc voltage measurement;
The size of the database: the number of tests (and therefore the number of nominal regions and arc regions-preferably sufficiently large, for example several hundred or thousand windows).

Further, in each measurement, the arc voltage and current measurements are time-correlated.

To learn information leading to a high true-positive rate (reliability aspect) and a low false-positive rate (robustness aspect), two categories of signals are required: electric arc signatures and nominal regions. Nominal regions are all signatures where an electric arc is not present. This therefore corresponds to nominal but also abnormal regimes (inrush, load reconfiguration, etc.) of electrical loads connected to the network and supplied by the cables under surveillance. The database must therefore contain the widest possible distribution of these signals (aeroplane loads, tests in severe representative environments).

Once they have been acquired, it may be advantageous to pre-process the measurements in order to facilitate their analysis. Therefore, in one embodiment, the acquisition phase of the process according to the invention includes a step of pre-processing the measurements acquired. This pre-processing step makes it possible, in particular, to standardise acquisitions and to eliminate offsets and faults in the measuring chain.

### Decision Function Design Phase

In one mode of implementation, the process 100 comprises a phase PC for designing a decision function using the plurality of measurements (possibly pre-processed as described previously), this phase being intended to determine a decision function as described previously, i.e. a function that takes as an input a plurality of descriptors extracted from an arc current measurement and gives as an output a Boolean (or any equivalent representation) representative of the presence or absence of an electric arc.

### Pre-Identification Step

Preferably, the design phase PC first includes a pre-identification step by expertise involving a rough identification (without precision to within one sample) of all electric arcs that meet predetermined criteria. For this first step, the expert roughly identifies all arcs across all tests of all the measurements. The identification is not precise to within one sample. It is simply a matter of defining the position of each arc within the acquisition data. An illustration of these data after pre-identification is given in [FIG. 4], wherein two arcs (Arc1 and Arc2) are identified by dotted circles.

In one embodiment, this pre-identification is performed on the basis of specification criteria such as minimum arc duration, minimum arc voltage, etc. In one embodiment, the measurements from the plurality of measurements are stored in one or more files, and the time position and number of arcs per measurement file are stored in a summary file.

Although optional, this step improves performance of the decision function obtained at the end of the design phase PC.

### Labelling Step

The learning phase includes a labelling step E11. In the present invention, the labelling step E11 is original in that it applies logic based on arc physics: for each measurement, it uses the arc voltage measurement (only available in the laboratory) as a reference to automatically label the arc current (or line current-available in the laboratory and which will be available later during the detection phase PD) measurement. During this step E11, an algorithm, which will be described below, scans all of the measurements in the plurality of measurements in order to precisely identify the arc start and end information in each arc voltage measurement, and thus select the relevant part (in other words, the labelled part corresponding to a measurement window) in each corresponding arc current measurement. The relevant part thus selected in each arc current measurement from the plurality of measurements is then used for learning. The windows thus labelled are labelled and saved. It is thus possible to label the data on the basis of criteria selected in advance (e.g., a threshold voltage Uₛ—see the detailed description of the labelling step hereinafter).

### Verification Step

Preferably, the design phase PC includes, at the end of the labelling step, a step of manually verifying the labelling by expertise. During this step, one or more experts verify the set of windows thus saved. During this step, windows that have not been labelled but nevertheless corresponding to the occurrence of an electric arc can thus be manually labelled. Likewise, incorrectly labelled windows (because the phenomenon has atypical characteristics) can be relabeled. As a general rule, labelled windows are saved, while other measurements are anonymised and removed from the saving. In other words, this step allows verifying that the measurements labelled include all the regions contemplated for learning, i.e. a window comprising part of the measurement prior to the formation of the arc, the measurement corresponding to the formation of the arc, as well as part of the measurement after the formation of the arc.

Although optional, this step can be useful because some arcs may not be correctly identified during the labelling step E11. This optional step can therefore help to improve the decision function obtained at the end of the design phase PC.

### Manual Identification Step

Preferably, the design phase PC includes, at the end of the labelling step, a step for manually identifying the remaining arcs, i.e. the missing arcs. During this step, a check is performed on the differences between the number and position of arcs identified during the pre-identification step (when the same is implemented) and during the labelling verification step (when the same is implemented). All arcs identified during the pre-identification step and not marked at the end of the labelling verification step are then manually marked, with the aim of labelling all arcs present in the measurements of the plurality of measurements.

Although optional, this step can therefore contribute to improving the decision function obtained at the end of the design phase PC.

### Descriptor Extraction Step

The design phase PC also comprises, for each of the plurality of measurements, a step E12 of extracting the descriptors from each window of the arc current measurement labelled during the labelling step E11. Indeed, to adjust a learning model, it is necessary to extract descriptors from a data window relating to each measurement representative of the phenomenon to be detected, this window having been identified during the labelling step E11. These descriptors are informative characteristics about the analysed measurement window and therefore about the phenomenon to be detected, herein the formation of an electric arc.

The extraction step E12 can be done in at least two different ways:
Using an unsupervised learning method such as autoencoders; in this case, the descriptors have no physical interpretation;
Using prior physical knowledge that may be contained in the measurement, such as:
   Frequency content, for example after a Fourier or wavelet transform;
   Statistical moments, such as a mean, standard deviation, kurtosis, and skewness;
   Time analyses.

Preferably, in the process 100 according to the invention, the descriptors are extracted using prior physical knowledge and include spectral entropy and/or autocorrelation of the arc current measurement over the selected window.

In one embodiment, the process comprises, after the descriptor extraction step, a step of normalising measurements of the plurality of measurements.

### Descriptor Classification and Selection Step

In one embodiment, the design phase PC also includes a step of classifying and selecting descriptors. Indeed, not all extracted descriptors necessarily have characteristics that can lead to the correct segregation of the two existing window classes (arcs and nominal). Thus, analysing the importance and level of correlation of the descriptors with the window label can be useful and improve performance of the decision function. Indeed, a poor descriptor can potentially disrupt the prediction, reducing (sometimes drastically) the final performance of the decision function. Descriptor selection can generally lead to better learning performance, such as greater efficiency, lower computational cost, and a more effective automatic arc detection model. Accordingly, this embodiment is particularly advantageous when there are a large number of descriptors.

Thus, the purpose of the descriptor selection step is to maximise relevance and minimise information redundancy. In one exemplary embodiment, this step is performed by a supervised filtering method.

In one exemplary embodiment, classification may be made using a Gram-Schmidt method and selection may be made using an incremental method. Of course, other methods can be used for classification or selection.

Although optional, this step can therefore contribute to improving the decision function obtained at the end of the design phase PC.

### Decision Function Determination Step

The design phase PC also includes a step E13 of determining the decision function, denoted f(X) below (where X represents descriptors extracted from the arc current measurement and provided as an input to the decision function).

In one embodiment, this step E13 comprises a plurality of iterations of the following two sub-steps:
a sub-step of designing a classifier through learning; and
a sub-step of validating the classifier from the data labelled.

Further, these sub-steps are repeated until the most effective classifier is obtained, i.e. for example the classifier that minimises, below a threshold, the classification error made on a base of data that have not been learned (so as to ensure generalisation capacity of said classifier). The decision function f(X) is determined from this classifier.

Thus, determining a classifier allows, through learning (corresponding to the plurality of iterations of the sub-steps described previously), to obtain an efficient classifier in order to make an effective decision.

In order to implement this step E13, several supervised classification methods can be used. The choice of method may be influenced especially by the desired detection time: some methods may have a higher computational complexity, but better performance. Preferably, the classification method used in this step is a support vector machine method. As this method is well known to those skilled in the art, it will not be further described herein.

In one alternative embodiment, the classification method is selected from one of the following methods:
Formal neural networks (simple, convolutional, recurrent);
Hidden Markov models;
K-nearest neighbours method;
Decision tree;
Ensemble learning (pairing two methods from among the methods listed previously).

All steps E11-E13 described above are implemented prior to the detection phase PD and, at the end of the design phase PC, the decision function (and therefore the detection strategy) is fixed. Therefore, descriptors selected during the design phase PC are the descriptors that will be used during the detection phase PD. During the detection phase PD, these same descriptors will therefore be extracted from the signals measured (example: via signal processing) and used as inputs to the decision function, which will assign the signal either to the “arc” category or to the “nominal regime” category (i.e. no electric arc).

### Detailed Description of the Labelling Step

In the following, in order to illustrate labelling step E11, the following notation is used:
t is the time considered;
t_{end} is the total duration of the current test;
Tₘₐₓ is the maximum window duration;
Tₘᵢₙ is the minimum window duration;
P_{g} is the left step; its value is normalised for the duration of the window under study and lies between [0,1];
P_{d} is the right step; P_{d}=1−P_{g}, it is therefore also a value normalised for the duration of the window under study and between [0,1];
t_{d} is the arc start time;
tₑ is the arc extinction time;
tₑᵥₐₗᵤₐₜᵢₒₙ is the evaluation time of the percentage of points that are above Uₛ before the start of an arc;
U_{arc} is the arc voltage;
I_{arc} is the arc current;
Uₛ is the minimum voltage threshold from which existence of an electric arc is considered to be true; this voltage threshold (or threshold voltage) is a function of knowledge of the arc physics.

As has been detailed previously, step E11 of labelling according to the invention is subsequent to the signal acquisition step or even to the signal pre-processing step. In the case of electrical signatures of fault arcs, the only information that can guarantee presence of an electric arc is the measurement of the voltage thereacross (the arc voltage), since this value will be zero in the absence of discharge and greater than some value only in the presence of an arc. As a reminder, the arc voltage information is not subject to measurement (because it is not available) during the detection phase PD. It is only accessible and used during the design phase PC. It is therefore from this information that the labelling strategy according to the invention is defined. In other words, the arc voltage measurement is used exclusively to label the current measurement (for the learning and validation data acquired in the laboratory) and this use is limited to the design phase PC.

Additionally, during labelling step E11, the characteristics of the phenomenon to be detected must be clearly defined. They represent the specificity of the fault that is being sought for detection.

In one exemplary embodiment, the characteristics of the arcs to be detected are as follows:
arc duration≥1 ms;
increase in arc voltage from 0 to a minimum of 10V.

In an exemplary embodiment, the characteristics of the windows labelled as arcs are as follows:
a window duration between 1 and 10 ms;
presence of a negative time shift with a duration proportional to the length of the window;
absence of an arc end signature (correlated with a drop in arc voltage to 0V).

These values are provided by way of example but do not represent a limitation to the invention.

In the state of the art, labelling is a delicate and time-consuming operation. However, in the process 100 according to the invention, this step E11 is automated, ensuring the same result as manual implementation while optimising the time spent.

For this, the labelling step E11 comprises, for each measurement and for each time interval t of the measurement considered, the following sub-steps:
when the arc voltage measured U_{arc} exceeds a predetermined threshold value Uₛ for the first time (i.e. at the first occurrence of the following relationship: U_{arc}(t)>Uₛ and U_{arc}(t−₁)<Uₛ where t is the interval considered), a step of recording the interval considered as the starting point of the electric arc (in other words t_{d}=t);
when the arc voltage U_{arc} measured falls below said predetermined threshold value Uₛ for the first time (i.e. at the first occurrence of the following relationship: U_{arc}(t)<Uₛ and U_{arc} (t−1)>Uₛ where t is the interval considered), a step of recording the interval preceding the interval considered (i.e. t−1) as the end point of the electric arc (in other words, tₑ=t−1).

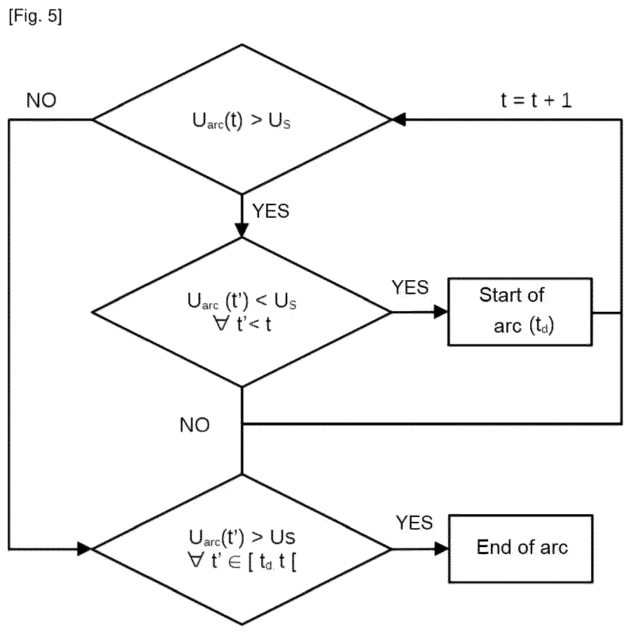

These two sub-steps are illustrated in the form of a flowchart in [FIG. 5]. In this flowchart, the arc voltage measured is compared to the threshold arc voltage. If the arc voltage measured is higher than the threshold arc voltage, the preceding arc voltage values are verified. If none of the preceding values were above this threshold value, it means that the arc voltage has exceeded the threshold value for the first time, signalling the start of the arc. Otherwise, no action is taken. Likewise, if the measured arc voltage value is below the threshold value and the threshold value was above a same threshold value, then this signals that the arc voltage has fallen back below this threshold value, signalling end of the arc.

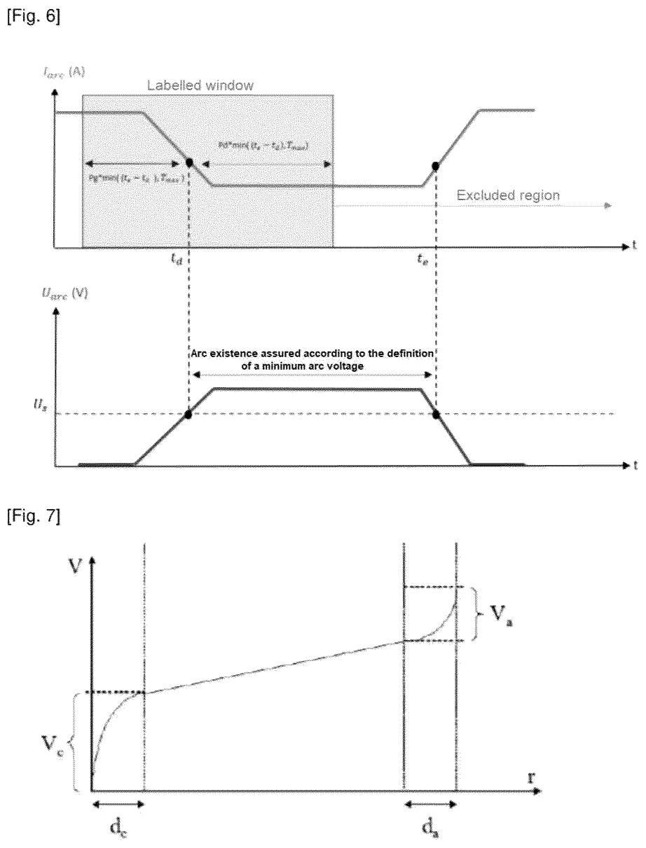

In one embodiment, for each measurement, the labelling is associated with a measurement window on which learning is performed, said window being given by the interval: [P_{g}×min((tₑ−t_{d}),Tₘₐₓ); P_{d}×min((tₑ−t_{d}),Tₘₐₓ)]. The descriptors will be extracted from the data in this interval. Such a measurement window is illustrated in [FIG. 6], which represents, at the top, the arc current as a function of time and, at the bottom, the arc voltage as a function of time. This is a simplified representation of electrical profiles appearing in the event of a series arc in DC voltage on an electrical system supplying a resistive load. In the example in [FIG. 6], the appearance of the arc is represented on the voltage curve by an increase in voltage of a few volts or a few tens of volts. On the current curve, this is represented by the appearance of a current drop occurring at the same instant. In addition to these drops, the labelling step seeks to retain a small part of the signal to the left of the drop (nominal region) and an even larger part of the signal to the right of the drop (established arc) in order to store a significant frequency content of the phenomenon. As already mentioned, the start of an arc, at time t_{d}, is first identified as the moment when the arc voltage measured U_{arc} exceeds a determined threshold value Uₛ, selected in relation to the arc physics. In one embodiment, the value of Uₛ is given by the sum of the anode and cathode voltage drops, for example a value of 20V for the sum of both voltage drops in air.

Once the start of the arc has been identified, its end (tₑ) is determined in a same way, but representing the moment when the voltage returns to a value below the established threshold. With this, it is possible to identify the duration of the analysed electric arc (d=tₑ−t_{d}). If this duration is greater than the maximum windowing value desired in the detection (Tₘₐₓ), this predefined maximum value is taken as a reference. Otherwise, where the arc duration is less than the established windowing duration and greater than the minimum duration (Tₘᵢₙ) acceptable for the arc, the arc duration is taken as the reference window. The regions to the right and left of t_{d} are then added together according to one percentage (P_{d}+P_{g}=1) of this reference duration. All arcs are then labelled in this way.

In one embodiment, the threshold voltage is determined from the course of the voltage measured across an electric arc as a function of the arc length, this course being set forth in [FIG. 7]. Three zones can be identified in this figure. In the zones located at the start and end of the arc, the arc voltage changes in a non-linear manner. These are the anode and cathode zones in which the arc voltage drop represents a significant, unavoidable value that is systematically greater than 0 V. In general, the values of V_{c}+Vₐ are between 10 and 25 V under the environmental conditions encountered in the aeronautics field. The third zone is the central zone, where the arc voltage increases linearly as a function of the distance travelled by the arc and is of no particular interest in the implementation of the process according to the invention. In other words, the appearance of an electric arc will systematically be accompanied with the production of an arc voltage whose value will be defined by a minimum threshold explained by voltage drops across the electrodes.

### Detection Phase

In order to detect the presence of an electric arc on an electric line, the method includes a detection phase PD subsequent to the design phase PC, in which the decision function obtained during the design phase PC will be used to determine whether or not an electric arc is present in a current measurement. Unlike the design phase (PC), where the arc voltage is an available measurement, in real conditions (outside the laboratory), i.e. during the detection phase (PD), only the arc current measurement may be available. Detection will therefore preferably be based on this measurement alone.

More particularly, the detection phase PD first includes a step E14 of measuring current flowing on the electric line. This step E14 is made continuously and in real time so as to enable rapid detection of the presence of an arc.

The detection phase PD also includes a step E15 of extracting descriptors from the current measurement. As already mentioned, the descriptors extracted during this step E15 are identical to those selected during the design phase PC and serve as input data for the decision function. They are additionally extracted continuously as the current measurements are acquired.

The detection phase PD also comprises a step E16 of detecting presence of an arc in the measurement of the current flowing on the electric line LI. This step uses the descriptors extracted from the current measurement and the decision function determined during the design phase PC.

In one embodiment, it is possible to cut off current in the electric line LI on which the detection is performed using a current cut-off device, and the process 100 according to the invention comprises, when an electric arc is detected during the detection step E16, a step of sending an instruction to cut off current on the line LI considered to the cut-off device MMC. This makes it possible to prevent or, at the very least, limit the damage associated with the formation of an electric arc on the electric line LI considered.

Quality of the detection depends on learning quality, which in turn depends on data quality and labelling. One of the contributions of the process according to the invention is to automate this labelling by using a plurality of measurements (generally carried out in a laboratory), each measurement comprising a time-correlated measurement of the arc voltage and the arc current.

### Device for Detecting Presence of an Electric Arc

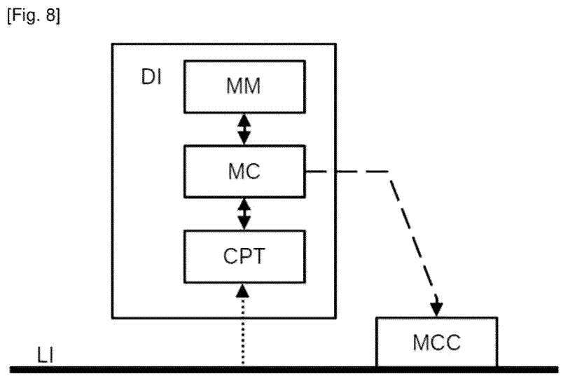

A second aspect of the invention illustrated in [FIG. 8] relates to a device DI comprising means configured to implement a process 100 according to the invention. More particularly, the device comprises a calculation means MC (example a processor or an ASIC card) associated with a memory MM (example a RAM and/or a hard disk), said memory MM being configured to store the data and instructions necessary for the implementation of the process 100 according to the invention. The device DI according to the invention also comprises a measurement means CPT configured to measure, in real time, the current passing through an electric line LI when the same is connected to such an electric line LI and to communicate the measurement to the calculating means MC of the device DI according to the invention. In one exemplary embodiment, the device is an RCCB (Remote Controller Circuit Breaker) or even an SSPC (Solid State Power Controller).

In one embodiment, the current passing through the electric line LI can be cut off by a remotely controllable current cut-off device MCC, and the device DI according to the invention is configured so that, when the presence of an arc is detected on the electric line LI, it sends an instruction to the current cut-off device MCC to cut off current in the electric line.

1. A computer-implemented process for detecting presence of an electric arc on an electric line using a machine learning method, the learning being performed using:
a plurality of measurements relating to the formation of an electric arc, each measurement of the plurality of measurements comprising a time-correlated measurement of the arc voltage V_{arc}, the current I and the source voltage V_{source};
a knowledge model relating the arc voltage V_{arc} and the current I to constants depending on the knowledge model;
the process being implemented using a learning model derived from a learning phase during which, using the plurality of measurements and the knowledge model, a step of adjusting the learning model is implemented, the learning model taking as inputs the current I and the source voltage V_{source} and providing as outputs the arc voltage V_{arc} and the constants of the knowledge model, the learning being performed using a cost function L given by the following relationship L=L₁+L₂ where L₁ is a first cost sub-function measuring a first difference between the arc voltage
$${V}_{arc}^{predit}$$
predicted by the learning model and the arc voltage V_{arc} measured:
$${L}_{1} = ‖ {V}_{arc}^{predit} - {V}_{arc} ‖ .$$
and where L₂ is a second cost sub-function measuring a second difference between the prediction of the knowledge model and the values measured;
the method comprising a detection phase including:
a step of continuously measuring the current and the source voltage V_{source} on the electric line, so as to acquire input data relating to the current I and the source voltage V_{source} over a measurement window
$${\{ I ( {t}_{m} ) , {V}_{source} \}}_{m = 1}^{M}$$
where M is the number of measurement points in the measurement window l is the current at time tₘ and V_{source} (tₘ) is the source voltage at time tₘ;
a step of continuously determining the presence of an arc, using a decision function for detecting, as a function of the M last input data relating to the current/and the source voltage V_{source} measured on the electric line during the measurement step, presence of an arc, the decision function being a function of the second cost sub-function.

2. The process according to claim 1, wherein the decision function is defined by the following expression:
$$f ( X ) = \{ \begin{matrix}Arc if {\sum }_{m = 1}^{M} {L}_{2} \leq ε \\ Else if {\sum }_{m = 1}^{M} {L}_{2} > ε\end{matrix}$$
Where Xₘ={t(tₘ), V_{source}}, ε is a detection threshold value, and L₂ is the value of the second cost sub-function L₂ determined using the learning model calculated at point Xₘ.

3. The process according to claim 2, wherein the knowledge model is the Mayr model and the second cost sub-function L₂ takes the following form:
$${L}_{2} = \frac{1}{I} \frac{dI}{dt} - \frac{1}{{V}_{arc}} \frac{{dV}_{arc}}{dt} - \frac{1}{τ} ( \frac{{V}_{arc} I}{{P}_{0}} - 1 )$$
where τ is the arc constant and P₀ is the cooling power.

4. The process according to claim 1, wherein the knowledge model is the Cassie model and the second cost sub-function L₂ takes the following form:
$${L}_{2} = \frac{1}{I} \frac{dI}{dt} - \frac{1}{{V}_{arc}} \frac{{dV}_{arc}}{dt} - \frac{1}{τ} ( \frac{{V}_{arc}^{2}}{{V}_{0}^{2}} - 1 )$$
where τ is the arc constant and V₀ is the minimum arc voltage.

5. The process according to claim 1, wherein the knowledge model is the Shavemaker model and the second cost sub-function L₂ takes the following form:
$${L}_{2} = \frac{1}{I} \frac{dI}{dt} - \frac{1}{{V}_{arc}} \frac{{dV}_{arc}}{dt} - \frac{1}{τ} ( \frac{{V}_{arc} I}{{P}_{0} + {V}_{0} \vert I \vert} - 1 )$$
where τ is the arc constant, P₀ is the cooling power, and V₀ is the minimum arc voltage.

6. The process according to claim 1, wherein the electric line is equipped with a cut-off device for cutting off the current in said line, the process comprising, when an electric arc is detected during the detection step, a step of sending an instruction to the cut-off device to cut off current on the line considered.

7. The process according to claim 1, wherein the process further comprises:
a phase of designing a decision function by machine learning, using the plurality of measurements, the design phase comprising:
for each measurement of the plurality of measurements, a step of labelling the arc current measurement using the arc voltage measurement associated therewith;
a step of extracting descriptors from the measurements labelled derived from the labelling step;
a step of determining the decision function, by machine learning, from at least one part of the descriptors extracted during the extraction step;
wherein the phase of detecting presence of electric arcs comprises:
a step of measuring the current flowing on the line;
a step of extracting descriptors from the current measurement obtained in the preceding current measurement step;
from a part of the descriptors extracted during the preceding step of extracting descriptors and using the decision function determined during the design phase, a step of detecting presence of arcs in the current measurement;
the labelling step comprising, for each measurement of the plurality of measurements and for each time interval t of the measurement considered:
when the arc voltage U_{arc} measured exceeds a predetermined threshold value U_{z} for the first time, a step of recording an interval considered to be the starting point t_{d} of the electric arc;
when the arc voltage U_{arc} measured falls back below the predetermined threshold value Uₛ for the first time, a step of recording the interval preceding an interval considered to be the end point tₑ of the electric arc.

8. The process according to claim 7, wherein, for each measurement, the labelling is associated with a measurement window on which the learning is made, said window being given by the interval [P_{g}×min((tₑ−t_{d}),Tₘₐₓ): P_{d}×min((tₑ−t_{d}),Tₘₐₓ)] where Tₘₐₓ is a predefined maximum window duration, P_{g} is a left pitch of t_{d} having a normalised value for the duration of the window under study, and P_{d} is a right pitch of t_{d} having a normalised value for the duration of the study window given by the relationship P_{d}=1−P₀.

9. The process according to claim 7, comprising, prior to the design phase, a signal acquisition step necessary for learning so as to obtain a plurality of measurements, each measurement comprising a time-correlated measurement of the arc voltage and the arc current.

10. The process according to claim 7, wherein the design phase comprises, prior to the labelling step, a step of manually pre-identifying by expertise, in each measurement of the plurality of measurements, all electric arcs satisfying predetermined criteria so as to define a position of each arc within each measurement of the plurality of measurements.

11. The process according to claim 7, wherein the design phase comprises, at the end of the labelling step, a step of manually verifying outputs of the labelling step by expertise so as to verify that the measurements labelled comprise all the regions contemplated for learning.

12. The process according to claim 7, wherein the descriptors used during the step of determining the decision function comprise the spectral entropy and/or autocorrelation of the arc current.

13. A device for detecting presence of an arc in a current line, the device comprising a measurement means configured to measure current flowing in the current Iine and means configured to implement a process according to claim 1.

14. (canceled)

15. A non-transitory computer-readable medium comprising instructions which, when executed by a computer, perform the process according to claim 1.

16. An aircraft comprising a detection device in accordance with claim 13.
